(19) United States
(12) Patent Application Publication
(10) Pub. No.: US 2015/0114448 A1
(43) Pub. Date: Apr. 30, 2015

(54) SOLAR MODULE AND SOLAR MODULE PRODUCTION METHOD

(71) Applicant: HANWHA Q CELLS GMBH, Bitterfeld-Wolfen (DE)

(72) Inventors: Johannes WENDT, Dresden (DE); Matthias HOFMANN, Leipzig (DE); Matthias HEIMANN, Dresden (DE)

(21) Appl. No.: 14/522,442

(22) Filed: Oct. 23, 2014

(30) Foreign Application Priority Data
Oct. 24, 2013 (DE) 102013111748.1

(51) Int. Cl. H01L 31/05; H01L 31/18

(52) U.S. Cl. CPC H01L 31/0512; H01L 31/0516; H01L 31/18
USPC 136/244; 438/98

(57) ABSTRACT

A solar module having at least one solar cell on the rear-side surface of which a metallization layer is formed, and having a further solar cell, which is electrically connected to the solar cell by means of a conductive connector, the rear-side surface of the solar cell having at least one first surface region, at which the metallization layer is formed with a first layer thickness, and a second surface region, at which the metallization layer has an opening or is formed with a second layer thickness, which is smaller than the first layer thickness, the connector being attached to the solar cell by means of an adhesively-bonded connection in the second surface region.

### PRIORITY CLAIM

The present application claims priority to German Patent Application No. 10 2013 111 748.1, filed on Oct. 24, 2013, which said application is incorporated by reference in its entirety herein.

### FIELD OF THE INVENTION

The present invention relates to a solar module and to a method for producing the solar module.

### BACKGROUND

Solar modules that include multiple interconnected solar cells are known. However, it is problematic to produce an adhesion between the solar cells and the connector that is stable in the long term.

### SUMMARY OF THE INVENTION

An embodiment of the invention comprises a solar module having a plurality of solar cells which are interconnected by means of at least one connector. The connector is attached to the solar cells by means of an adhesively bonded connection. In order to produce a good efficacy of the solar module, the connector must be well adhered to the solar cells. Furthermore, it should be possible for the electric current from the solar cells to be conveyed well into the connector.

An object of the invention is to provide a solar module that has solar cells formed in such a way that a satisfactory adhesiveness and electrical contact between said solar cells and the connector can be achieved.

In accordance with the invention, the object is achieved by a solar module and a solar module production method.

The invention relates to a solar cell module having at least one solar cell, on the rear-side surface of which a metallization layer is formed, and having a further solar cell, which is electrically connected to the solar cell by means of a conductive connector, the rear-side surface of the solar cell having at least one first surface region, on which the metallization layer is formed with a first layer thickness, and a second surface region, on which the metallization layer has an opening or is formed with a second layer thickness, which is smaller than the first layer thickness, the connector being attached to the solar cell by means of an adhesively bonded connection in the second surface region.

The invention is based on the consideration that the connector adheres better to a surface region having a metallization layer with lower or no layer thickness (that is to say directly on the underlying semiconductor or dielectric surface) by means of an adhesively bonded connection than to a surface region having a metallization layer with greater layer thickness. Metallization layers with greater layer thickness are relatively porous, and therefore a connection there often fails, because the adhesive bond in the layer is less. By contrast, a connection between the connector and a metallization layer with lower layer thickness may tear only in particles forming the metallization layer or at interfaces between the connector of the metallization layer and the adhesive, and therefore higher forces are necessary in order to bring the connection to failure. Metallization layers with lower layer thickness generally have a greater density and therefore a lower porosity.

It has been found that a solar module having at least one solar cell with a metallization layer that is provided at the first surface region with a first layer thickness and that is provided at the second surface region optionally with a second layer thickness which is either smaller compared with the first layer thickness or is not provided at all on the one hand meets the requirements for electric contact between the solar cell and the connector and on the other hand simultaneously meets the requirements for stable adhesiveness between the solar cell and the connector when the connector is attached to the solar cell by means of an adhesively bonded connection at least in the second surface region.

The solar cell, on the rear-side surface of which a metallization layer is formed, can be electrically connected to the front or rear side of the further solar cell by means of the conductive connector.

In an embodiment, the second surface region is surrounded by the first surface region. In this case, the second surface region is formed as a recess or opening in the metallization layer. The solar cell has an edge region with a uniform layer thickness when the first surface region surrounds the second surface region.

The summed total area of all second surface regions preferably corresponds to less than 30%, less than 20% or less than 10% of the rear-side surface of the solar cell. This proportion of the second surface region is sufficient to ensure good electrical contact and good adhesiveness between solar cell and connector.

The width of the connector and of the adhesion promoter are preferably equal to or smaller than the width of the second surface region. The length of the connector or the direction of extension thereof extends preferably beyond the rear-side surface of the solar cell, and therefore the solar cell can be connected by means of the connector to a further solar cell. In a preferred embodiment the second surface region along the rear-side surface has a width between 0.5 mm and 5 mm or between 1 mm and 3 mm and/or a length between 3 mm and 20 mm or between 5 mm and 15 mm.

The connector can be attached to the solar cell at points or over areas, in particular over the entire area, by means of the adhesively bonded connection in the second surface region. In other words, the connection between the connector and the solar cell can be formed at the second surface region along the direction of extension of the connector for connection of the solar cell to a further solar cell in such a way that the connector is attached in the direction of the extension thereof over the entire area or at points in the second surface region, whereas the width of the connector is preferably selected such that it is equal to or narrower than the width of the second surface region. The connector can be adapted to the metallization layer topography and can be formed in such a way that it is connected to the metallization layer at the first and second surface regions. The connector may also be attached on the metallization layer or in contact therewith at the first surface regions. A connection or attachment of the connector to the solar cell also at the first surface region or the first surface regions is used in particular to reduce the electrical resistance between the metallization layer and the connector.

The connector is preferably stretched along the direction of extension thereof, and a plurality of second surface regions are distanced from one another on the rear-side surface along the direction of extension. The connector is attached to the solar cell by means of the adhesively bonded connection at each of the plurality of second surface regions distanced from one another. By means of the formation of a plurality of second surface regions along the direction of extension of the connector, a plurality of adhesion regions are formed along the direction of extension of the connector. The adhesiveness between the solar cell and the connector can thus be improved further. In this embodiment, the second surface regions, which have an improved adhesiveness to the connector compared with the first surface regions, alternate in the direction of extension with first surface regions, which have improved electrical contact with the connector compared with the second surface regions. When the first surface regions are connected to the connector by means of an adhesively bonded connection, the adhesiveness and the electrical contact between the connector and the solar cell are also improved.

The metallization layer is preferably formed from aluminium. Aluminium is a good electrical conductor and is an inexpensive material compared with silver, for example. The metallization layer may be formed from aluminium only in the first surface region when the second surface region is formed as an opening in the metallization layer. Alternatively, the metallization layer is formed from aluminium in the first surface region and in the second surface region. The formation of the metallization layer in the second surface regions from the same material as in the first surface regions facilitates the production of the metallization layer.

The metallization layer is preferably a paste metallization. Alternatively or additionally, the metallization layer is a thin film. The metallization layer is preferably a paste metallization when the second surface region is formed as an opening in the metallization layer. In a further preferred embodiment, the metallization layer is a paste metallization when a metallization layer with the second layer thickness is formed at the second surface region. In an embodiment that is improved further still, the metallization layer is preferably a paste metallization at the first surface region and a thin film at the second surface region, when a metallization layer with the second layer thickness is formed at the second surface region.

Thin-film metallizations are preferably produced by means of physical or chemical deposition methods, preferably with plasma assistance. By contrast, paste metallizations are preferably produced by applying a metallization paste, in particular an aluminium paste, by means of screen printing and by then subjecting the solar cell with the applied metallization paste to a firing process, in which it is exposed to a temperature of a few hundred degrees Celsius, such that the metallization layer forms from the metallization paste.

In the embodiment that the metallization layer is formed with the second layer thickness at the second surface region, the metallization layer is preferably formed from a first partial metallization layer with the second layer thickness and from a second partial metallization layer, the connector being attached on the first partial metallization layer at the second surface region. In other words, the metallization layer has the second partial metallization layer at the first surface region. The second partial metallization layer is preferably formed from the same material as the first partial metallization layer, but may also comprise another material. The first partial metallization layer can be formed, for example, by removing material from the second partial metallization layer, and therefore the first partial metallization layer with the second layer thickness is present at the second surface region, and the second partial metallization layer is present at the first surface region. In this case, the metallization layer is preferably formed as paste metallization. The first partial metallization layer may also be produced separately from the second partial metallization layer, for example when, during the production of the solar cell, the first partial metallization layer with the second layer thickness has been formed first, and then the second partial metallization layer has been formed. In this case, the first partial metallization layer is preferably formed as a thin film, and the second partial metallization layer is preferably formed as paste metallization.

Furthermore, the connector at the first surface region preferably rests on the second partial metallization layer and/or is in contact therewith. The adhesiveness and electrical contact between the solar cell and the connector are thus improved further.

In an embodiment, the first partial metallization layer is formed as thin-film metallization or as paste metallization, and the second partial metallization layer is formed as paste metallization. When the first partial metallization layer is formed as thin-film metallization, the porosity of the metal layer is reduced compared with a paste metallization, when the metal is aluminium for example. The adhesive force between the solar cell and the connector is improved by a reduced porosity.

In the embodiment that the metallization layer at the second surface region is formed with the second layer thickness, the second layer thickness lies in a range between 1 μm and 15 μm or in a range between 3 μm and 10 μm. Alternatively, the second layer thickness is smaller than 15 gm or 10 μm. The first layer thickness preferably lies in the range between 25 and 50 μm, preferably between 30 and 40 μm.

The connector is preferably attached to the solar cell in the second surface region by means of a conductive adhesive. The conductive adhesive is preferably an anisotropic conductive adhesive. By using a conductive adhesive as adhesively bonded connection, that is to say an adhesive with electrically conductive components, the electrical contact between the solar cell and the connector is influenced advantageously.

The invention also relates to a solar cell production method, in which a solar cell is metallized on the rear side by producing a metallization layer on a rear-side surface of the solar cell in such a way that the metallization layer is formed at least at a first surface region with a first layer thickness and the metallization layer at a second surface region has an opening or is formed with a second layer thickness that is smaller than the first layer thickness.

The metallization layer with different layer thicknesses at first and second surface regions of the rear-side surface of the solar cell can be produced in different ways. By way of example, the metallization layer is produced on the rear-side surface of the solar cell, whereas a mask masks the second surface region, and therefore the metallization layer is formed only at the first surface region. Alternatively, the metallization layer can be produced over the entire area on the rear-side surface of the solar cell and can be deposited at the second surface region at least in part. Furthermore, a first partial metallization layer can alternatively be produced on the rear-side surface of the solar cell either over the entire area or at the second surface region, and a second partial metallization layer can then be produced on the rear-side surface of the solar cell at the first surface region.

### BRIEF DESCRIPTION OF THE FIGURES

The invention will be explained hereinafter on the basis of exemplary embodiments with reference to the figures, in which:

FIG. 1 depicts a side view of a solar module;

FIG. 2 depicts a side view of a further solar module;

FIG. 3 depicts a partial plan view of the solar module depicted in FIG. 1; and

FIG. 4 depicts a partial plan view of the further solar module depicted in FIG. 2.

### DETAILED DESCRIPTION

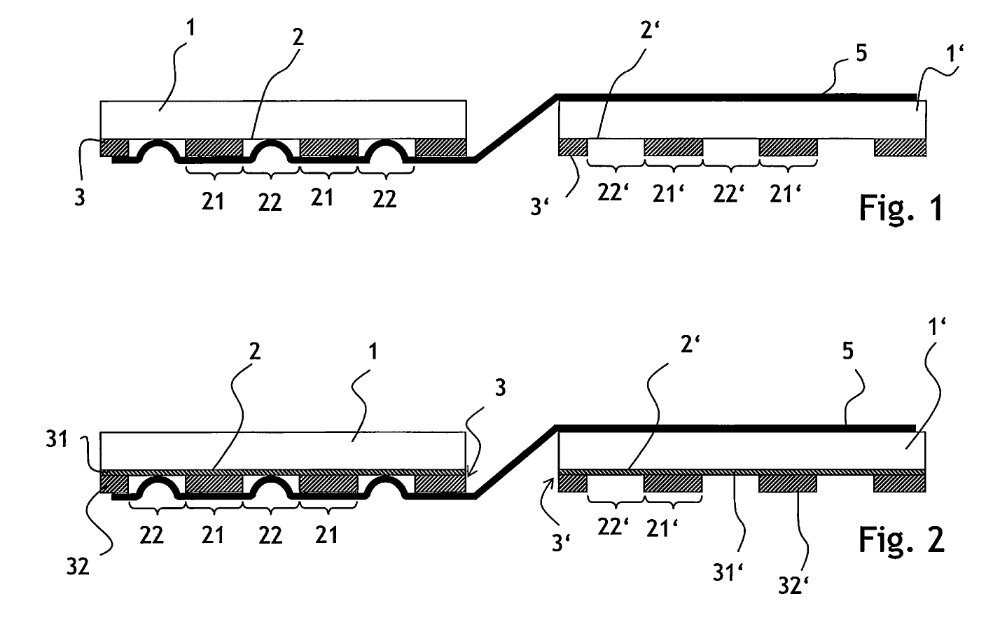

FIG. 1 depicts a side view of a solar module: The solar module shown in FIG. 1, for illustration of the principle of the invention, has a solar cell 1 and a further solar cell 1′, the number being selected purely randomly. The solar cell 1 has a rear-side surface 2. A metallization layer 3 is formed on the rear-side surface 2 of the solar cell 1. The rear-side surface 2 of the solar cell 1 has a plurality of first surface regions 21, at which the metallization layer 3 is formed with a first layer thickness, and a plurality of second surface regions 22, at which the metallization layer 3 has an opening. A rear-side surface 2′ of the further solar cell 1′ has an accordingly formed metallization layer 3′ at a plurality of first surface regions 21′ and a plurality of second surface regions 22′. A connector 5 is attached to the solar cell 1 by means of an adhesively bonded connection (not shown) in the second surface region 22 and rests on the solar cell 1 at the first surface region 21. The connection of the connector 5 to the solar cell 1 is formed at points at the second surface regions. The connector 5 connects the rear side of the solar cell 1 to a front side of the further solar cell 1′.

FIG. 2 depicts a side view of a further solar module. The solar module shown in FIG. 2, for illustration of the principle of the invention, likewise has a solar cell 1 and a further solar cell 1′, the number being selected purely randomly. The solar cell 1 has a rear-side surface 2. A metallization layer 3 is formed on the rear-side surface 2 of the solar cells 1. The metallization layer 3 has a first partial metallization layer 31 with a second layer thickness, which is arranged on the rear-side surface 2 at first surface regions 21 and second surface regions 22. The metallization layer 3 further has a second partial metallization layer 32, which is arranged on the first partial metallization layer 31 at the first surface regions 21 on the side of the partial metallization layer 31 facing away from the rear-side surface 2. The further solar cell 1′ has a rear-side surface 2′ with a metallization layer 3′ formed in a manner corresponding to the metallization layer 3 with a plurality of first surface regions 21′ and a plurality of second surface regions 22′. A connector 5 is attached to the solar cell 1 by means of an adhesively bonded connection (not shown) at the second surface regions 22 and rests on the solar cell 1 at the first surface regions 21. The connector 5 connects the rear side of the solar cell 1 to a front side of the further solar cell 1′.

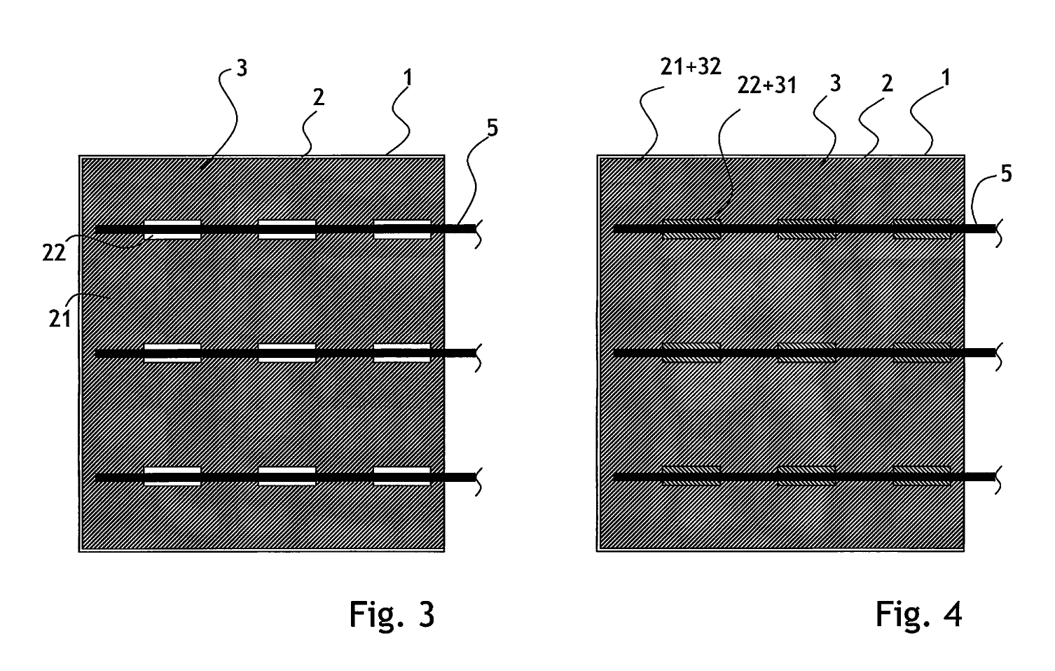

FIG. 3 depicts a partial plan view of the solar module shown in FIG. 1, in particular a plan view of the solar cell 1. The solar cell 1 has the rear-side surface 2 with metallization layer 3 formed thereon. The rear-side surface 2 of the solar cell 1 has the first surface regions 21, at which the metallization layer 3 is formed with a first layer thickness, and the second surface regions 22, at which the metallization layer 3 has an opening. The first surface regions 21 surround the surface regions 22. The second surface regions 22 each have a length that is greater than the width of said second surface regions. The connectors 5 extend along the first surface regions 21 and the second surface regions 22 in the longitudinal extension of the second surface regions 22.

FIG. 4 depicts a partial plan view of the solar module shown in FIG. 2, in particular a plan view of the solar cell 1. The solar cell 1 has the rear-side surface 2 with metallization layer 3 formed thereon. The second partial metallization layer 32 is visible in the first surface regions 21, whereas the first partial metallization layer 31 is visible at the second surface regions 22. The second surface regions 22 each have a length that is greater than the width of said second surface regions. The connectors 5 extend along the first surface regions 21 and the second surface regions 22 in the longitudinal extension of the second surface regions 22.

### LIST OF REFERENCE NUMERALS

1 solar cell

1′ further solar cell

2 rear-side surface

3 metallization layer

5 connector

21 first surface region

21′ first surface region

22 second surface region

22′ second surface region

31 first partial metallization layer

32 second partial metallization layer

1. A solar module comprising a first solar cell defining a rear-side surface, a metallization layer being formed on the rear-side surface, and a second solar cell electrically connected to the first solar cell by a conductive connector, the rear-side surface of the first solar cell having at least one first surface region, at which the metallization layer is formed with a first layer thickness, and a second surface region, at which the metallization layer has an opening or is formed with a second layer thickness, which is smaller than the first layer thickness, the connector being attached to the solar cell by an adhesively-bonded connection in the second surface region.

2. The solar module according to claim 1, wherein the second surface region is surrounded by the first surface region.

3. The solar module according to claim 1, wherein a summed total area of the second surface region corresponds to less than 30%, less than 20% or less than 10% of the rear-side surface of the solar cell.

4. The solar module according to claim 1, wherein the second surface region along the rear-side surface has a width between 0.5 mm and 5 mm or between 1 mm and 3 mm and/or a length between 3 mm and 20 mm or between 5 mm and 15 mm.

5. The solar module according to claim 1, wherein the connector is stretched along a direction of extension, and in that a plurality of second surface regions are distanced from one another on the rear-side surface along the direction of extension, the connector being attached to the solar cell by the adhesively-bonded connection at each of the plurality of second surface regions distanced from one another.

6. The solar module according to claim 1, wherein the metallization layer is formed from aluminium.

7. The solar module according to claim 1, wherein the metallization layer is a paste metallization and/or a thin film.

8. The solar module according to claim 1, wherein the metallization layer is formed with the second layer thickness at the second surface region, and is formed from a first partial metallization layer with the second layer thickness and from a second partial metallization layer, the connector being attached to the first partial metallization layer at the second surface region.

9. The solar module according to claim 1, wherein the metallization layer at the second surface region is formed with the second layer thickness, and is formed from a first partial metallization layer and from a second partial metallization layer with the first layer thickness, the connector resting on and/or being in contact with the first surface region on the second partial metallization layer.

10. The solar module according to claim 8, wherein the first partial metallization layer is formed as thin-film metallization or as paste metallization, and the second partial metallization layer is formed as paste metallization.

11. The solar module according to claim 1, wherein the metallization layer at the second surface region is formed with the second layer thickness, and the second layer thickness lies in a range between 1 μm and 15 μm or in a range between 3 μm and 10 μm, or the second layer thickness is smaller than 15 μm or 10 μm.

12. The solar module according to claim 1, wherein the connector is attached to the first solar cell in the second surface region by a conductive adhesive.

13. A solar cell production method, in which a solar cell is metallized on a rear side by producing a metallization layer on a rear-side surface of the solar cell in such a way that the metallization layer is formed at least at a first surface region with a first layer thickness, and the metallization layer at a second surface region has an opening or is formed with a second layer thickness that is smaller than the first layer thickness.

14. The solar module according to claim 12, wherein the conductive adhesive comprises an anistropic conductive adhesive.
